(19) United States
(12) Patent Application Publication
(10) Pub. No.: US 2006/0091516 A1
(43) Pub. Date: May 4, 2006

(54) Flexible leaded stacked semiconductor package

(76) Inventor: Akira Matsunami, Beppu-city (JP)

Correspondence Address: TEXAS INSTRUMENTS INCORPORATED, P O BOX 655474, M/S 3999, DALLAS, TX, 75265, US

(21) Appl. No.: 10/979,694

(22) Filed: Nov. 1, 2004

(51) Int. Cl. H01L 21/48; H01L 23/495

(52) U.S. Cl. 257/686; 438/109; 257/676; 438/123

(57) ABSTRACT

A multi-chip semiconductor device comprises two semiconductor assemblies vertically aligned so that the second active chip surface (110a) faces the first active chip surface (101a) and forms a gap (120) between the assemblies. Encapsulation material (130) fills the gap and couples the first and second assemblies together to form the multi-chip device (100). Lead portions of the first and second leadframes remain exposed from the encapsulation material. The exposed leads (104) of the first leadframe may be comprised for leadless assembly, and the exposed leads (114a) of the second leadframe may be formed coplanar with the first leads (104).

### FIELD OF THE INVENTION

The present invention is related in general to the field of semiconductor devices and processes, and more specifically to assembly methods for integrated circuit chips resulting in stacked multichip devices in a single package.

### DESCRIPTION OF THE RELATED ART

It is advantageous for many applications of semiconductor devices to arrange the needed devices in close proximity. When only two, or few more, semiconductor chips are needed, various arrangements have been proposed in order to achieve the desired proximity, and to enable a minimization of required space. Typically, these arrangements are planar assemblies of semiconductor chips on a substrate, with or without a specific encapsulation. For these arrangements, the term “multichip module” is commonly used. For an encapsulated assembly, the term “multichip package” has been introduced. For many years, there has been a rather limited market for multichip modules and multichip packages, but driven by the rapidly expanding penetration of integrated circuit applications into small, often hand-held, products, this market is recently growing significantly. In order to participate in this market, the multichip products have to meet several conditions.

The multichip product has to offer the customer performance characteristics not available in single-chip products. This means, the multichip product has to leapfrog the development of a single-chip product.

The multichip product has to be available to the customer at short notice. This means, the multichip product should use readily available components and fabrication methods.

The multichip product has to offer the customer a cost advantage. This means, the design and fabrication of the multichip product has to avoid unconventional or additional process steps.

The multichip product has to offer low cost-of-ownership. This means, it has to operate reliably based on built-in reliability.

Numerous multichip packages have been described in publications and patents. In most instances, the chips are assembled side by side on a planar substrate and interconnected by means of this substrate. In some proposals, though, the chips are stacked, but usually interconnected by techniques, which turn out to be not cost-effective in fabrication (beam lead technology, tape automated bonding, multi-level substrates, etc.).

A number of these arrangements have recently been summarized in U.S. Pat. No. 6,316,822, issued on Nov. 13, 2001 (Venkateshwaran et al., “Multichip Assembly Semiconductor”). The cited patent itself suffers from a lack of package pins. Next to small package area consumption, the potential for high number of input/output pins is, however, one of the key product requirements for multichip assemblies.

### SUMMARY OF THE INVENTION

A need has therefore arisen for a coherent, low-cost, high pin-count method of fabricating multichip packages based on available chip designs and assembly and encapsulation techniques. The method should be based on chip-stacking technology in order to reduce assembly area consumption.

It is a technical advantage that the method is be flexible enough to be applied for different semiconductor product families and a wide spectrum of design and process variations. Furthermore, it is a technical advantage that the multichip assembly delivers high-quality and high-reliability products. It is another technical advantage that these innovations are accomplished while shortening production cycle time and increasing throughput.

One embodiment of the invention is a multi-chip semiconductor device comprising two semiconductor assemblies vertically aligned so that the second active chip surface faces the first active chip surface and forms a gap between the assemblies. Encapsulation material fills the gap and couples the first and second assemblies together to form the multi-chip device. The first semiconductor assembly comprises a first chip having an active surface including a plurality of bond pads, and a passive surface, and a first leadframe having a chip mount pad and a plurality of leads. The passive chip surface is attached to the chip mount pad, and the bond pads are electrically conductive connected to the leads, respectively. The second semiconductor assembly comprises a second chip having an active surface including a plurality of bond pads, and a passive surface and a second leadframe having a plurality of leads. The active chip surface is attached to the leads by means of an adhesive insulator, and the bond pads are electrically conductive connected to the leads, respectively.

Lead portions of the first and second leadframes remain exposed from the encapsulation material. The exposed leads of the first leadframe may be comprised for leadless assembly, and the exposed leads ends of the second leadframe may be formed coplanar with the first leads. In another embodiment, the passive surface of the fist chip may remain exposed from molding compound to allow the attachment of a heat sink.

Another embodiment of the invention comprises a method for fabricating a multichip semiconductor device. A first semiconductor assembly is fabricated by providing a first semiconductor chip having an active surface including a plurality of bond pads, and a passive surface, and a first leadframe having a chip mount pad and a plurality of leads. Next, the passive chip surface is attached to the chip mount pad, and the bond pads are electrically conductive connected to the leads, respectively. A second semiconductor assembly is fabricated by providing a second semiconductor chip having an active surface including a plurality of bond pads, and a passive surface, and a second leadframe having a plurality of leads. Next, the active chip surface is attached to the leads by means of an adhesive insulator, and the bond pads are electrically conductive connected to the leads, respectively.

The second assembly is vertically aligned with the first assembly so that the second active chip surface faces the first active chip surface and forms a gap between the assemblies. The gap is filled with encapsulation material and concurrently the first and second assemblies are coupled together to the said multi-chip device.

The vertical alignment of first and second assemblies is preferably achieved during the loading process of the mold cavity, especially for devices having the first assembly using a leadframe of the leadless category. After the molding step, the forming of the leads of the second leadframe provides lead ends coplanar with the leadless leadframe of the first assembly, resulting in a multichip device suitable for an area-conserving attachment to external parts.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section of a stacked multichip semiconductor device according to an embodiment of the invention.

FIG. 2 illustrates the top view of an external part showing the footprints for attachment of a multichip device having coplanar leads according to an embodiment of the invention.

FIG. 3 shows a schematic cross section of a stacked multichip semiconductor device having an attached heat sink according to another embodiment of the invention.

FIGS. 4A to 6 illustrate process steps for fabricating the assemblies and the stacked multichip device according to another embodiment of the invention.

FIG. 4A shows a schematic cross section of the chip and leadframe of the first assembly.

FIG. 4B shows a schematic cross section of the chip wire-bonded to the leadframe of the first assembly.

FIG. 5A shows a schematic cross section of the chip and leadframe of the second assembly.

FIG. 5B shows a schematic cross section of the chip wire-bonded to the leadframe of the second assembly.

FIG. 6 shows a schematic cross section of the closed mold cavity after the first and second assemblies have been placed and vertically aligned inside the cavity for the molding step.

### DETAILED DESCRIPTION OF THE PREFERRED EMBODIMENTS

FIG. 1 displays an embodiment of the invention; the schematic cross section shows a stacked multichip semiconductor device, generally designated 100, comprising two semiconductor assemblies. The first assembly comprises a first chip 101, which has an active surface 101a including an integrated circuit and/or operating discrete components, and a plurality of bond pads 102; chip 101 also has a passive surface 101b. The first semiconductor assembly further has a first leadframe consisting of a chip mount pad 103 and a plurality of leads 104. In the example of FIG. 1, leads 104 are configured as metal pieces shaped for a leadframe designed for a so-called “leadless device”. Leads 104 provide the input/output terminals for the first semiconductor assembly and may be attached to external parts (for example, by pressure contact or by soldering).

For many devices, chip 101 is made of silicon; other alternatives include silicon germanium, gallium arsenide or other semiconductor materials. The chip thickness ranges typically from about 100 to 300 μm. The first leadframe is commonly made of copper or copper alloys; other alternatives include aluminum and invar. The leadframe thickness ranges typically from about 100 to 200 μm.

The passive surface 101b of chip 101 is attached to the chip pad 103 using conventional chip attach material 105 such as adhesive epoxy or polyimide (which may be silver-filled for better thermal conductivity).

Bond pads 102 are electrically conductive connected to leads 104. The preferred method of connection is wire ball bonding 106, especially by automated bonding techniques resulting in low loop heights. Alternatively, low-looped ribbon bonding using wedge stitching may be employed. Preferred wire or ribbon materials include gold or gold alloys; alternatives include copper and aluminum.

The second assembly comprises a chip 110, which has an active surface 110a including an integrated circuit and/or operating discrete components, and a plurality of bond pads 112; chip 110 also has a passive surface 10b. The second semiconductor assembly further has a second leadframe consisting of a plurality of leads 114; however, the second leadframe does need a chip mount pad. In the example of FIG. 1, leads 114 provide the input/output terminals for the second semiconductor assembly; in addition, the outer lead ends 114a have a shape to provide attachment to externals parts (by soldering or pressure contacts). Preferably, second lead ends 114a are coplanar with first lead 104.

For many devices, chip 101 is made of silicon; other alternatives include silicon germanium, gallium arsenide or other semiconductor materials. The chip thickness ranges typically from about 100 to 300 μm. The first leadframe is commonly made of copper or copper alloys; other alternatives include aluminum and invar. The leadframe thickness ranges typically from about 100 to 200 μm.

Portions of the active surface 110a of chip 110 are attached to one surface of the inner lead ends 114b by means of an adhesive insulator layer 115. Preferred insulator material includes polyimide in the layer thickness range of about 1 μm.

Bond pads 112 are electrically conductive connected to the opposite surface of the inner lead ends 114b of leads 114. The preferred method of connection is wire ball bonding 116, especially by automated bonding techniques resulting in low loop heights. Alternatively, low-looped ribbon bonding using wedge stitching may be employed. Preferred wire or ribbon materials include gold or gold alloys; alternatives include copper and aluminum.

As FIG. 1 shows, the second assembly is vertically aligned with the first assembly so that the second active chip surface 110a faces the first active chip surface 101a and forms a gap 120 between these surfaces 110a and 101a. For practical reasons, the gap 121 separating the bonding loops of wires 116 and 106 is more consequential for controlling the vertical alignment of the first assembly and the second assembly. Major contributions to this control are the bending and forming of the second leadframe leads 114 and the loop height control of wires 116 and 106.

FIG. 1 indicates that gap 120 is filled by encapsulation material 130. This material 130 further couples the first assembly and the second assembly together so that the multichip device 100 is formed with controlled outlines 131. The transfer molding process using a mold cavity and epoxy molding compound filled with inorganic anhydrides is the preferred technique to accomplish the filling of gap 120, the controlled outlines of device 100, and internal adhesion and high reliability of the finished device. Using the advanced controls available in the transfer molding technique, provides also tight control over the device thickness 140 achievable. Total device thicknesses 140 of less than 1 mm have been accomplished.

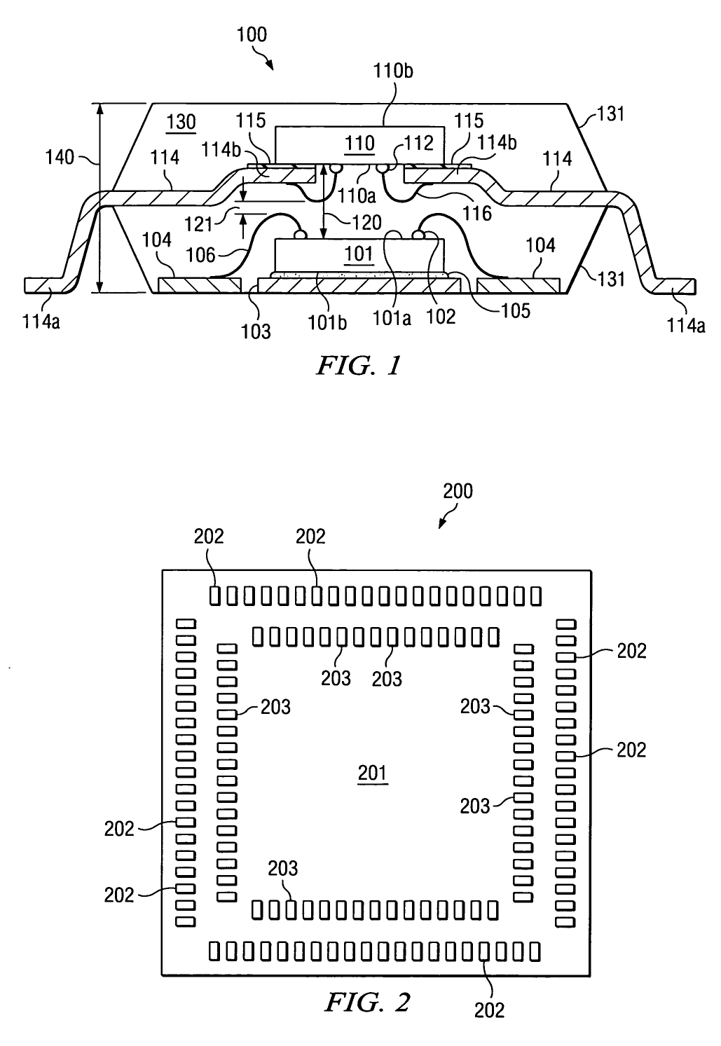

FIG. 2 is a schematic top view of an external part such as a substrate or motherboard, generally designated 200, for the attachment of multichip device 100. Shown is insulating substrate 201 with an outer linear array of metallic contact pads 202 and an inner array of contact pads 203. In this example, the attachment of multichip device 100 is by solder reflow, preferably using a solder made of tin or a tin alloy. The outer pads 202 are designed to be contacted by lead ends 114a (see FIG. 1) and the inner pads 203 by lead portions 104. The substrate 201 of FIG. 2 is intended for coplanar leads 114a and 104. There are, however, other external parts 200, which provide pad row 202 at a level different from the level of pad row 203. In those cases, leads 114a and 104 may not be coplanar, but at different levels.

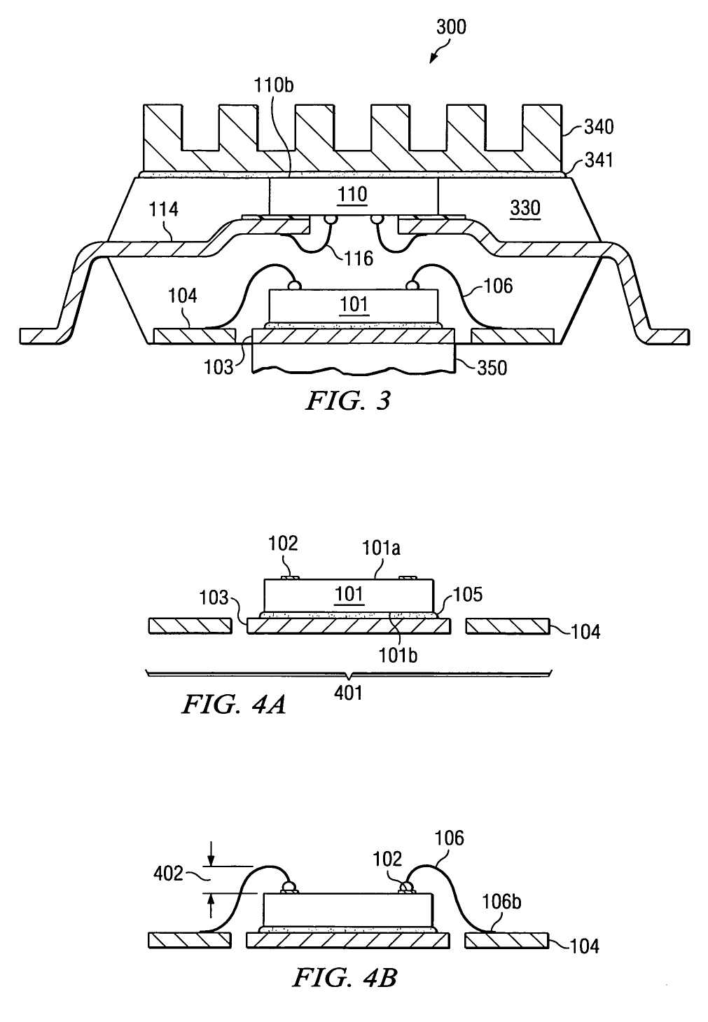

The schematic cross section of FIG. 3 illustrates another embodiment of the invention, generally designated 300. The encapsulation material 330 has been applied so that the passive surface 10b of the second chip 110 remains exposed. Consequently, a heat sink 340 can be attached to chip 110. The adhesive attach material 341 is thin and may be metal-filled (preferably silver-filled).

The thermal performance of multichip device 300 is especially good, when concurrently the chip pad 103 of the first leadframe is in contact with a cooled or heat sink external part 350. In this case, both chips 101 and 110 experience steep temperature gradients to the environment and thus enjoy excellent cooling and thermal operational performance.

FIG. 4A to 6 illustrate process steps for fabricating the assemblies and the stacked multichip device according to another embodiment of the invention. Since the individual chips of the multichip device are not mounted next to each other on a plane and wire bonded in one process step, but rather stacked vertically, the process steps of chip mounting and wire bonding are performed separately for each member assembly.

In the schematic cross section of FIG. 4A, the initial step of the fabrication method assembles first chip 101 onto first leadframe 401. Chip 101 is provided with an active surface 101a having an integrated circuit, possibly other active components, and bond pads 102, and a passive surface 101b. Leadframe 401 is provided with a chip mount pad 103 and a plurality of leads 104. In the example of FIG. 4A, these leads 104 are designed for use in a so-called leadless assembly, meaning that they do not exhibit lead portions, which need to be formed in a later process step. Passive chip surface 101b is attached to chip pad 103 using a polymer adhesive 105.

In the process step depicted in FIG. 4B, wire ball bonds 106 connect bond pads 102 with the leads 104. Obviously, the stitch sites 106b of leads 104 have to be suitable for stitch attachment, for instance by a silver or palladium spot on the copper leadframe. Although the bonding is “downhill”, meaning along the chip sides, to leads 104, the loop height 402 is preferably kept low in order to aim for thin overall device contour in the final assembly of the multichip device.

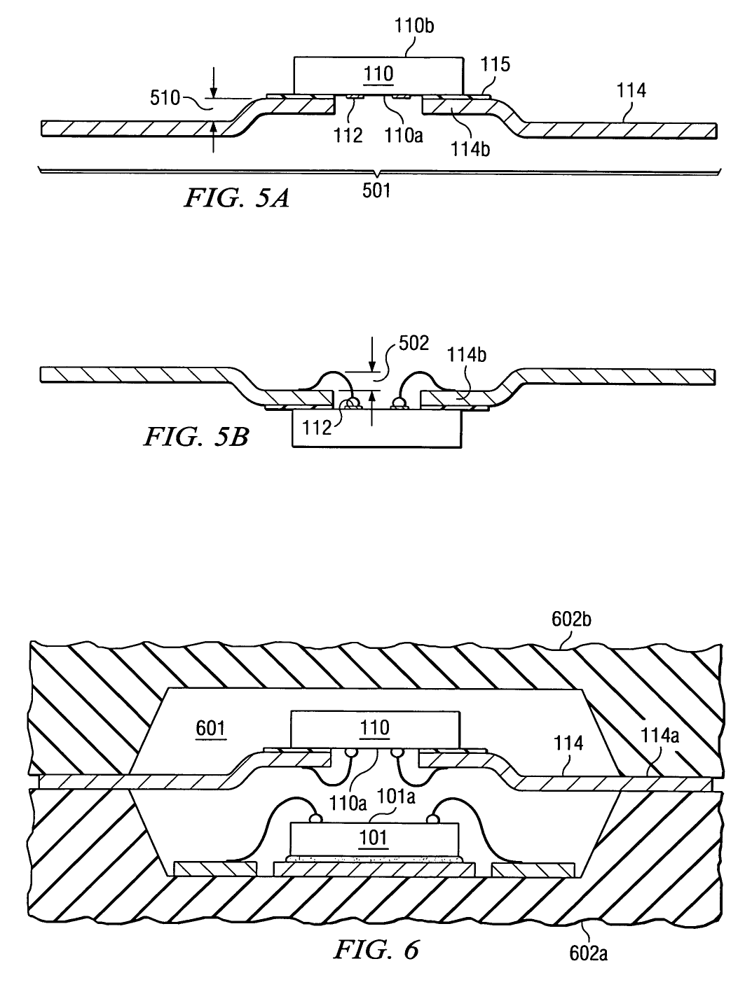

The schematic cross section of FIG. 5A illustrates the initial step of the fabrication method for the second chip 110 onto second leadframe 501. Chip 110 is provided with an active surface 110a having an integrated circuit, possibly other active components, and bond pads 112, and a passive surface 110b.

Leadframe 501 is provided with a plurality of leads 114. In the example of FIG. 5A, these leads 114 are designed with a step 510, which is formed when the leadframe is stamped from the original metal sheet. Step 510 is typically small and may not be needed in other embodiments. In the embodiment of FIGS. 5A to 6, the step in the lead is used to facilitate the alignment of the second assembly over the first assembly to create the multichip device, and to provide a “balanced” distribution of molded material above and below the leads as the center line. This feature helps to equalize the internal stress distribution in a molded package after the volumetric shrinkage of the molding compound during the curing cycle.

Active chip surface 110a is attached to one surface of the inner lead ends 114b by means of an adhesive insulator layer 115. After this process step, the assembly is inverted (see FIG. 5B) to complete the wire bonding operation, whereby the chip bond pads 112 are connected with the opposite surface of the inner lead ends 114b. Care is taken to keep loop height 502 low in order to aim for thin overall device contour in the final assembly of the multichip device.

The schematic cross section of FIG. 6 illustrates the alignment step of the second assembly with the first assembly in the cavity 601 of the mold equipment 602a and 602b before the molding process. The first assembly is placed on the bottom of the mold cavity of the bottom mold half 602a, the bottom surface of leadframe 401 touching the steel of mold half 602a. The active surface 101a of the first chip 101 is facing upward. The second assembly is placed over the first assembly so that the active surface 110a of chip 110 is facing downward towards the active surface 101a of chip 101. The outer lead ends 114a of leads 114 rest on the bottom mold half 602a. The second assembly is adjusted until chip 110 is centered and aligned with chip 101. The upper mold half 602b is then closed and pressed against bottom mold half 602a. The molding compound is transferred into cavity 601 to fill the cavity and any assembly gaps.

After completing the molding process, the encapsulated multichip product is taken from the press for curing the compound and forming the outer leads 114a. For the embodiment illustrated in FIG. 6, the outer leads 114a are pressed into the gull wing shape shown in FIG. 1.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the material of the semiconductor chip may comprise silicon, silicon germanium, gallium arsenide, or any other semiconductor or compound material used in IC manufacturing.

As another example, the chips of the first and second assembly may have significantly different sizes and different numbers of input/output pads.

As another example, there may be more than two chips, whereby either more than one chip are placed on one leadframe, or more than two leadframe are in the mold cavity. In the latter case, the forming of the leads which remain exposed from the molding compound is preferably done at different angles.

It is therefore intended that the appended claims encompass any such modifications or embodiments.

I claim:

1. A multichip semiconductor device comprising:
a first semiconductor assembly comprising:
a first chip having an active surface including a plurality of bond pads, and a passive surface;
a first leadframe having a chip mount pad and a plurality of leads;
said passive chip surface attached to said chip mount pad; and
said bond pads electrically conductive connected to said leads, respectively;
a second semiconductor assembly comprising:
a second chip having an active surface including a plurality of bond pads, and a passive surface;
a second leadframe having a plurality of leads;
said active chip surface attached to said leads by means of an adhesive insulator; and
said bond pads electrically conductive connected to said leads, respectively;
said second assembly vertically aligned with said first assembly so that said second active chip surface faces said first active chip surface and forms a gap between said assemblies; and
encapsulation material filling said gap and coupling said first and second assemblies together to form said multichip device.

2. The device according to claim 1 wherein said electrically conductive connections are wire bonds.

3. The device according to claim 1 wherein said first leadframe is comprised for leadless assembly configuration.

4. The device according to claim 1 wherein said second leadframe is comprised for leaded assembly configuration.

5. The device according to claim 1 wherein said encapsulation material comprises a molding compound.

6. The device according to claim 5 wherein said molding compound forms a balanced package for said device.

7. The device according to claim 1 wherein lead portions of said first and second leadframes remain exposed from said encapsulation material.

8. The device according to claim 7 further having said exposed leads of said first and second leadframes formed so that the lead ends are coplanar and thus provide a means of attaching said device to external parts in an area-conserving manner.

9. The device according to claim 1 wherein said passive surface of said second chip remains exposed from said encapsulation material.

10. The device according to claim 9 further having a heat sink attached to said exposed passive surface of said second chip.

11. The device according to claim 1 wherein the surface of said chip mount pad opposite to said attached first chip remains exposed from said encapsulation material.

12. The device according to claim 11 further having a heat sink attached to said exposed chip mount pad surface.

13. A method for fabricating a multichip semiconductor device comprising the steps of:
fabricating a first semiconductor assembly comprising the steps of:
providing a first semiconductor chip having an active surface including a plurality of bond pads, and a passive surface;
providing a first leadframe having a chip mount pad and a plurality of leads;
attaching said passive chip surface to said chip mount pad;
electrically conductive connecting said bond pads to said leads, respectively;
fabricating a second semiconductor assembly comprising the steps of:
providing a second semiconductor chip having an active surface including a plurality of bond pads, and a passive surface;
providing a second leadframe having a plurality of leads;
attaching said active chip surface to said leads by means of an adhesive insulator;
electrically conductive connecting said bond pads to said leads, respectively;
vertically aligning said second assembly with said first assembly so that said second active chip surface faces said first active chip surface and forms a gap between said assemblies; and
filling said gap with encapsulation material and concurrently coupling said first and second assemblies together to from said multi-chip device.

14. The method according to claim 13 wherein said step of filling said gap comprises a transfer molding step.

15. The method according to claim 14 wherein said molding step leaves portions of said first and second leadframe exposed.

16. The method according to claim 15 further comprising the step of forming said exposed lead portions of said first and second leadframes so that the lead ends become coplanar and thus suitable for attaching said multi-chip device to external parts in an area-conserving manner.

17. The method according to claim 13 wherein said step of connecting said bond pads to said leads comprises wire bonding.

18. The method according to claim 13 further comprising the step of attaching a heat sink to an exposed portion of said leadframes or said chips.

19. The method according to claim 13 wherein said step of vertically aligning comprises the step of placing said first leadframe on the bottom of the mold cavity, followed by the step of supporting said leads of said second leadframe by the cavity rims to control said gap between said aligned first and second assemblies.
